(19) United States
(12) Patent Application Publication
(10) Pub. No.: US 2026/0059764 A1
(43) Pub. Date: Feb. 26, 2026

(54) FERROELECTRIC MEMORY, THREE-DIMENSIONAL FERROELECTRIC MEMORY, AND THREE-DIMENSIONAL FERROELECTRIC MEMORY DEVICE

(71) Applicant: CXMT Corporation, Hefei City (CN)

(72) Inventors: Huihui LI, Hefei City (CN); Yi TANG, Hefei City (CN); Hao MENG, Hefei City (CN); KAI HUNG ALEX SEE, Hefei City (CN)

(73) Assignee: CXMT Corporation, Hefei City (CN)

(21) Appl. No.: 19/218,681

(22) Filed: May 27, 2025

Related U.S. Application Data
(63) Continuation of application No. PCT/CN2025/079461, filed on Feb. 27, 2025.

(30) Foreign Application Priority Data
Aug. 26, 2024 (CN) 202411183485.2

(51) Int. Cl. H10B 53/30; G11C 5/06; G11C 5/10; H10B 53/20; H10D 1/68

(52) U.S. Cl. CPC H10B 53/30; G11C 5/063; G11C 5/10; H10B 53/20; H10D 1/714

(57) ABSTRACT

Provided are a ferroelectric memory, a three-dimensional ferroelectric memory, and a three-dimensional ferroelectric memory device. The ferroelectric memory includes a first word line, a first bit line, a first transistor, and a first ferroelectric capacitor pair. The first ferroelectric capacitor pair includes a first ferroelectric capacitor and a second ferroelectric capacitor, and the first ferroelectric capacitor and the second ferroelectric capacitor extend in a first direction. A control terminal of the first transistor is connected to the first word line. A second terminal of the first transistor is connected to the first bit line, and a first terminal of the first transistor is connected to upper electrode plates of the ferroelectric capacitor pair.

### CROSS-REFERENCE TO RELATED APPLICATIONS

This application is a continuation of International Application No. PCT/CN2025/079461 filed on Feb. 27, 2025, which claims priority to Chinese Patent Application No. 202411183485.2 filed on Aug. 26, 2024. The disclosures of the above-referenced applications are hereby incorporated by reference in their entirety.

### BACKGROUND

The development of information technology requires low latency and large capacity of a memory. The low latency helps increase a data processing speed. The large capacity helps increase a storage density and reduce manufacturing costs of the memory.

A ferroelectric memory as a novel memory has received widespread attention because of the features of non-volatile data storage and high access rate. However, most of current ferroelectric memories are of a planar structure. Due to physical dimensions and characteristics of devices, a scaling speed of ferroelectric memories with a planar structure gradually slows down, and it is difficult to further increase the storage density. Therefore, how to increase the storage density and capacity of ferroelectric memories is currently a challenge in the development of ferroelectric memories.

### SUMMARY

Based on this, embodiments of this application provide a ferroelectric memory, a three-dimensional ferroelectric memory, and a three-dimensional ferroelectric memory device including the three-dimensional ferroelectric memory, so as to provide a high storage density.

This application relates to the technical field of integrated circuits, and in particular, to a ferroelectric memory, a three-dimensional ferroelectric memory, and a three-dimensional ferroelectric memory device including the three-dimensional ferroelectric memory.

In a first aspect, this application provides a ferroelectric memory according to some embodiments, including:
a first word line, a first bit line, a first transistor, and a first ferroelectric capacitor pair.

The first ferroelectric capacitor pair includes a first ferroelectric capacitor and a second ferroelectric capacitor, and the first ferroelectric capacitor and the second ferroelectric capacitor extend in a first direction.

A control terminal of the first transistor is connected to the first word line. A second terminal of the first transistor is connected to the first bit line, and a first terminal of the first transistor is connected to upper electrode plates of the first ferroelectric capacitor pair.

In a second aspect, this application further provides a three-dimensional ferroelectric memory according to some embodiments, including:
a substrate;
multiple first bit lines, multiple first word lines, and multiple first transistors, where the multiple first word lines, the multiple first bit lines, and the multiple first transistors are located on the substrate;
the multiple first bit lines extend in a first direction and are arranged in a second direction, the multiple first word lines extend in the second direction and are arranged in the first direction, the multiple transistors are arranged in the first direction and the second direction, and the first direction and the second direction intersect; and
multiple first ferroelectric capacitor pairs. Each of the first ferroelectric capacitor pairs includes a first ferroelectric capacitor and a second ferroelectric capacitor. The first ferroelectric capacitor and the second ferroelectric capacitor extend in the first direction and are arranged in a third direction. The first direction, the second direction, and the third direction intersect with each other.

Control terminals of the first transistors are connected to the first word lines. Second terminals of the first transistors are connected to the first bit lines, and first terminals of the first transistors are connected to upper electrode plates of the first ferroelectric capacitor pairs.

In a third aspect, this application further provides a three-dimensional ferroelectric memory device according to some embodiments, including:
a three-dimensional ferroelectric memory, where the three-dimensional ferroelectric memory is the three-dimensional ferroelectric memory provided in the second aspect; and
a peripheral device wafer, where the peripheral device wafer is coupled to the three-dimensional ferroelectric memory.

### BRIEF DESCRIPTION OF DRAWINGS

To describe the technical solutions in the embodiments of this application or the conventional technologies more clearly, the following briefly describes the accompanying drawings required for describing the embodiments or the conventional technologies. Clearly, the accompanying drawings in the following description show merely some embodiments of this application, and a person of ordinary skill in the art may still derive other drawings from these accompanying drawings without creative efforts.

FIG. 1 is a schematic structural diagram of a ferroelectric memory according to an embodiment of this application;

FIG. 2 is a schematic structural diagram of a ferroelectric memory according to an embodiment of this application;

FIG. 3 is a schematic structural diagram of a ferroelectric memory according to an embodiment of this application;

FIG. 4 is a schematic structural diagram of a ferroelectric memory according to an embodiment of this application;

FIG. 5 is a schematic structural diagram of another ferroelectric memory according to an embodiment of this application;

FIG. 6 is a schematic structural diagram of another ferroelectric memory according to an embodiment of this application;

FIG. 7 is a schematic structural diagram of another ferroelectric memory according to an embodiment of this application;

FIG. 8 is a schematic structural diagram of another ferroelectric memory according to an embodiment of this application;

FIG. 9 is a schematic structural diagram of a three-dimensional ferroelectric memory according to an embodiment of this application;

FIG. 10 is a schematic structural diagram of a three-dimensional ferroelectric memory according to an embodiment of this application;

FIG. 11 is a schematic structural diagram of a three-dimensional ferroelectric memory according to an embodiment of this application;

FIG. 12 is a schematic structural diagram of a three-dimensional ferroelectric memory according to an embodiment of this application;

FIG. 13 is a schematic structural diagram of another three-dimensional ferroelectric memory according to an embodiment of this application; and

FIG. 14 is a schematic structural diagram of a three-dimensional ferroelectric memory device according to an embodiment of this application.

### DESCRIPTIONS OF REFERENCE NUMERALS

100: substrate; 101: first bit line (second bit line); 102: first transistor; 103: first word line; 104: first ferroelectric capacitor; 105: second ferroelectric capacitor; 106: first ferroelectric capacitor pair; 107: first conducting wire; 108: second conducting wire; 109: connecting part; 110: insulating part; 202: second transistor; 203: second word line; 1041: first lower electrode; 1042: first ferroelectric dielectric layer; 1043: first upper electrode plate; 1044: third lower electrode; 1051: second lower electrode; 1052: second ferroelectric dielectric layer; 1053: second upper electrode plate; 1054: fourth lower electrode; 1062: third ferroelectric dielectric layer; 1063: third upper electrode plate; 300: peripheral device wafer.

### DETAILED DESCRIPTION

For ease of understanding of this application, this application is described more comprehensively below with reference to related accompanying drawings. A preferred embodiment of this application is provided in the accompanying drawings. However, this application may be implemented in many different forms, and is not limited to the embodiments described herein. Instead, these embodiments are provided to make the disclosure of this application more thorough and comprehensive.

Unless otherwise defined, all technical and scientific terms used herein have meanings the same as those commonly understood by a person skilled in the art of this application. In this application, terms used in the specification of this application are merely intended to describe objectives of specific embodiments, but are not intended to limit this application.

It should be understood that an element or a layer may be directly on, adjacent to, or connected to another element or layer or there may be an intermediate element or layer when the element or the layer is referred to as “on . . . ”, “adjacent to . . . ”, or “connected to . . . ”It should be understood that although the terms “first”, “second”, and the like may be utilized to describe various elements, components, regions, layers, doping types, and/or portions, these elements, components, regions, layers, doping types, and/or portions should not be limited by these terms. These terms are merely utilized to distinguish one element, component, region, layer, doping type, or portion from another element, component, region, layer, doping type, or portion. Therefore, without departing from the teachings of this application, a first element, component, region, layer, doping type, or portion discussed below may be represented as a second element, component, region, layer, or portion. For example, a first doped region may be referred to as a second doped region, and similarly, a second doped region may be referred to as a first doped region. The first doped region and the second doped region are different doped regions.

Spatial relationship terms, e.g., “on . . . ”, may be utilized herein to describe a relationship between an element or a feature and another element or feature shown in the figures. It should be understood that in addition to the orientations shown in the figures, the spatial relationship terms further include different orientations of devices in use and operation. For example, an element or a feature described as “on . . . ” is oriented to be “below” another element or feature if the devices in the accompanying drawings are flipped. Therefore, the example term “on . . . ” may include orientations of being on and being below. In addition, the devices may alternatively be otherwise oriented (rotated by 90° or oriented in another manner), and the spatial descriptors utilized herein are interpreted accordingly.

As employed herein, the singular forms of “a/an”, “one”, and “the” may also be intended to include plural forms unless otherwise clearly specified in the context. It should be further understood that, the presence of the feature, integer, step, operation, element, and/or component can be determined without ruling out the presence or addition of one or more other features, integers, steps, operations, elements, components, and/or groups when the term “constitute” and/or the term “include” are/is employed in the specification. Moreover, as employed herein, the term “and/or” includes any and all combinations of the related items listed.

The embodiments of the present disclosure are described herein with reference to a cross-sectional view serving as a schematic diagram of an ideal embodiment (and an intermediate structure) of this application. In this way, a variation in the shown shape caused by, e.g., a manufacturing technology and/or a tolerance can be expected. Therefore, the embodiments of this application should not be limited to specific shapes of the regions shown herein, but include a shape deviation caused by, e.g., a manufacturing technology. The regions shown in the figure are essentially examples. The shapes of the regions do not represent actual shapes of the regions of the device, and do not limit the scope of this application.

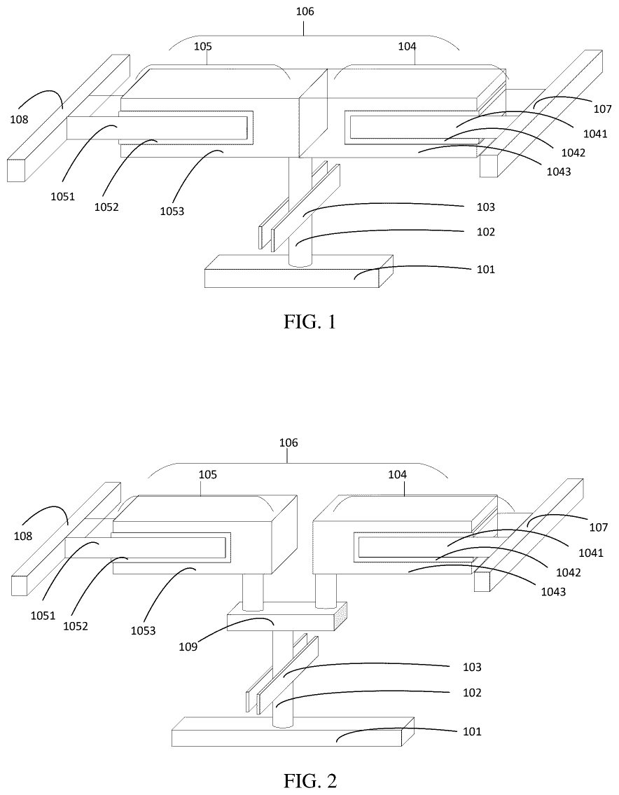

FIG. 1 is a schematic structural diagram of a ferroelectric memory according to an embodiment of this application. In some embodiments, the ferroelectric memory includes a first word line 103, a first bit line 101, a first transistor 102, and a first ferroelectric capacitor pair 106. The first ferroelectric capacitor pair 106 includes a first ferroelectric capacitor 104 and a second ferroelectric capacitor 105, and the first ferroelectric capacitor 104 and the second ferroelectric capacitor 105 extend in a first direction. The first transistor 102 includes a first terminal, a second terminal, and a control terminal. The control terminal of the first transistor 102 is connected to the first word line 103. The second terminal of the first transistor 102 is connected to the first bit line, and the first terminal of the first transistor 102 is connected to upper electrode plates of the first ferroelectric capacitor pair. The first ferroelectric capacitor 104 and the second ferroelectric capacitor 105 extend in the first direction, so that a storage capacity of the ferroelectric capacitors can be adjusted by adjusting the length in the first direction. This solves a sensing margin problem, and provides a sufficient floor area for the first transistor 102, which helps optimize a driving capability of the first transistor 102.

In some embodiments of this application, an NMOS (N-channel metal-oxide-semiconductor, N-channel metal-oxide-semiconductor) transistor, or a PMOS (P-channel metal-oxide-semiconductor, P-channel metal-oxide-semiconductor) transistor may be selected as the first transistor in the ferroelectric memory. For example, in a memory cell shown in FIG. 1, an NMOS transistor is selected as the first transistor. In this case, when a high voltage is applied to the first word line, the first transistor is turned on, or when a low voltage is applied to the first word line, the first transistor is turned off. In another embodiment, the first transistor may be a gate all around (gate all around), a triple gate, a double gate or a vertical single gate, or may be a planar transistor, a recessed transistor, or a buried transistor. A channel material of the first transistor 102 may be one or more of silicon (Si), polysilicon (poly-Si, p-Si), amorphous silicon (amorphous-Si, a-Si), an indium gallium zinc oxide (In—Ga—Zn—O, IGZO) multicomponent compound, zinc oxide (ZnO), ITO, titanium dioxide (TiO₂), molybdenum disulfide (MoS₂), and other semiconductor materials. This is not specifically limited in the embodiment of this application. In the embodiment of this application, only an example in which the first transistor 102 is a vertical double-gate transistor is taken for description.

Still referring to FIG. 1, in some embodiments, the control terminal of the first transistor 102 is referred to as a gate, and one of a drain (drain) or a source (source) of a MOS transistor is referred to as a first terminal, while the corresponding other terminal is referred to as a second terminal. For example, the first terminal of the first transistor may be the source while the second terminal may be the drain, or the first terminal is the drain while the second terminal is the source. The control terminal of the first transistor 102 is connected to the first word line 103, and the second terminal of the first transistor 102 is connected to the first bit line 101. The first bit line 101 and the first word line 103 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first word line 103 and the first bit line 101 may be made of the same material or different materials.

Still referring to FIG. 1, in some embodiments, the ferroelectric memory further includes a first ferroelectric capacitor pair 106. The first ferroelectric capacitor pair 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053. The first ferroelectric dielectric layer 1042 and the second ferroelectric dielectric layer 1052 each are made of a material that may include a perovskite structure material, e.g., barium titanate (BaTiO₃) and a mixture Pb (Zr,Ti)O₃ of lead zirconate (PbZrO₃) and lead titanate (PbTiO₃), and may further include an HfO₂-based ferroelectric material implemented by doping at least one of zirconium (Zr), silicon (Si), lanthanum (La), yttrium (Y), strontium (Sr), gadolinium (Gd), and aluminum (Al) in an HfO₂ material. A material and a manufacturing process of a ferroelectric film layer are not limited in this application.

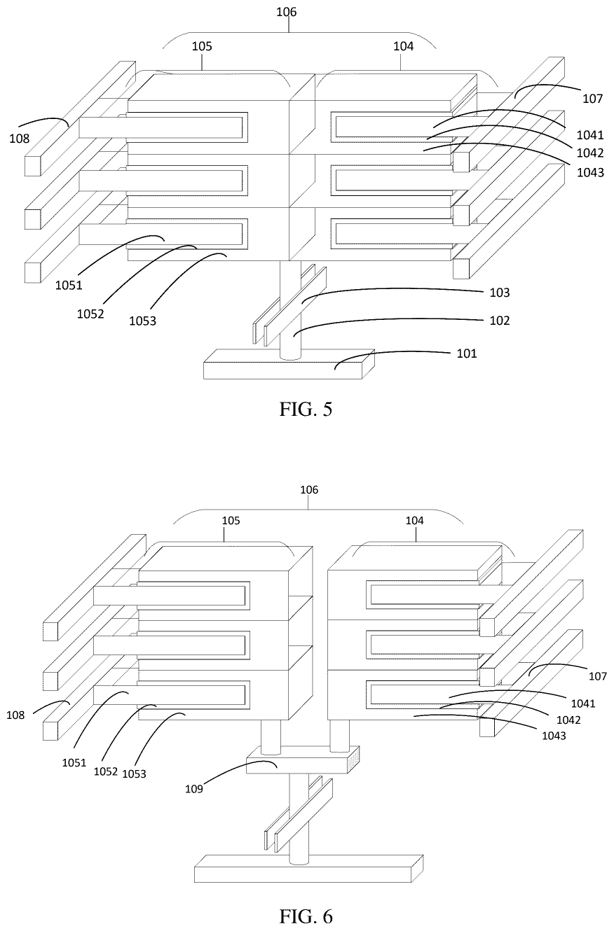

Still referring to FIG. 1, in some embodiments, the first lower electrode 1041, the second lower electrode 1051, the first upper electrode plate 1043, and the second upper electrode plate 1053 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first lower electrode 1041, the second lower electrode 1051, the first upper electrode plate 1043, and the second upper electrode plate 1053 may be made of the same material or different materials. The first upper electrode plate 1043 is in contact with the second upper electrode plate 1053, and the first terminal of the first transistor 102 is connected to the first upper electrode plate 1043 and the second upper electrode plate 1053. Similarly, referring to FIG. 5, there may be multiple first ferroelectric capacitor pairs 106. Each of the first ferroelectric capacitor pairs 106 is stacked in a third direction (away from the transistor), and the first upper electrode plate 1043 and the second upper electrode plate 1053 of each of the first ferroelectric capacitor pairs 106 are in contact to be connected into a whole, which is connected to the first terminal of the first transistor 102. The multiple first ferroelectric capacitor pairs 106 are stacked in the third direction and are jointly connected to the first transistor 102. This can reduce a quantity of transistors and increase a storage density. In addition, the first upper electrode plate 1043 and the second upper electrode plate 1053 of each of the first ferroelectric capacitor pairs 106 are in contact, so that the upper electrode plates can be integrally formed. This reduces the difficulty of a manufacturing process, shortens a manufacturing time of the process, improves production efficiency, and reduces production costs.

Still referring to FIG. 1, in some embodiments, the ferroelectric memory further includes a first conducting wire 107 and a second conducting wire 108. The first conducting wire 107 is connected to the first lower electrode 1041, and the second conducting wire 108 is connected to the second lower electrode 1051. The first conducting wire 107 and the second conducting wire 108 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first conducting wire 107 and the second conducting wire 108 may be made of the same material or different materials.

FIG. 2 is a schematic structural diagram of a ferroelectric memory according to an embodiment of this application. In some embodiments, a first ferroelectric capacitor pair 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053. The first upper electrode plate 1043 is not in direct contact with the second upper electrode plate 1053. A connecting part 109 is arranged at a first terminal of a first transistor. The connecting part 109 is separately connected to the first upper electrode plate 1043 and the second electrode plate 1053. A cross-section of the connecting part may be elliptical, rectangular, bench-shaped, or in another shape that enables the first upper electrode plate 1043 and the second upper electrode plate 1053 that are not connected to each other to be connected to the first transistor 102. The connecting part 109 is made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like.

Still referring to FIG. 2, in some embodiments, the first upper electrode plate 1043 and the second upper electrode plate 1053 are not in contact with each other, but are separately connected to the first transistor 102 through the connecting part 109. This can reduce crosstalk between the first ferroelectric capacitor 104 and the second ferroelectric capacitor 105 and improve performance of the ferroelectric memory. Similarly, referring to FIG. 6, there may be multiple first ferroelectric capacitor pairs 106. Each of the first ferroelectric capacitor pairs 106 is stacked in a third direction, and the first upper electrode plate 1043 and the second upper electrode plate 1053 of each of the first ferroelectric capacitor pairs 106 are not in contact. However, multiple first upper electrode plates 1043 are stacked and connected together to be connected to the first terminal of the first transistor 102 through the connecting part 109, and multiple second upper electrode plates 1053 are stacked and connected together to be connected to the first terminal of the first transistor 102. The multiple first ferroelectric capacitor pairs 106 are stacked in the third direction and are jointly connected to the first transistor 102. This can reduce a quantity of transistors and increase a storage density. In addition, the first upper electrode plate 1043 and the second upper electrode plate 1053 of each of the first ferroelectric capacitor pairs 106 are not in contact with each other, and can be manufactured separately, thereby increasing a manufacturing window of the process, reducing the difficulty of a manufacturing process, and improving production efficiency.

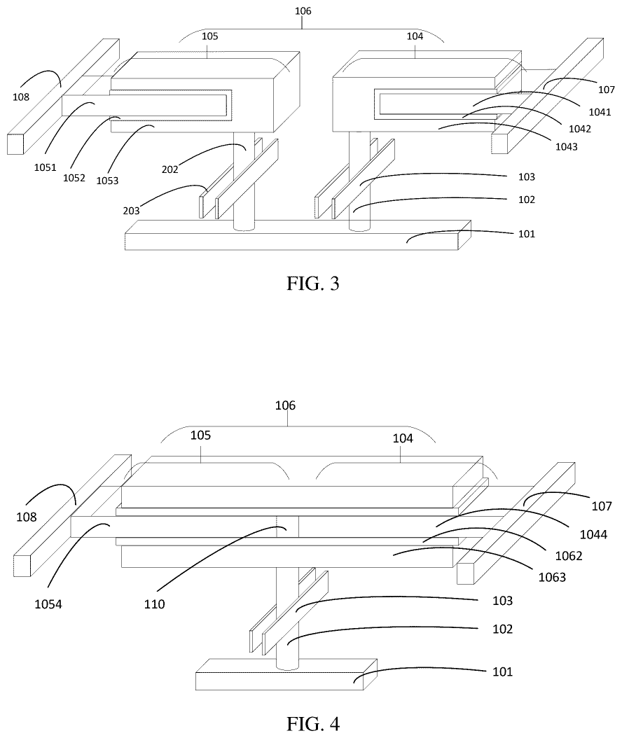

FIG. 3 is a schematic structural diagram of a ferroelectric memory according to an embodiment of this application. In some embodiments, the ferroelectric memory further includes a second transistor 202, a second word line 203, and a second bit line 101 (the second bit line and the first bit line may be shared or separated). A control terminal of the second transistor 202 is connected to the second word line 203. A second terminal of the second transistor 202 is connected to the second bit line 101. A first terminal of the second transistor 202 and the first terminal of the first transistor 102 are respectively connected to upper electrode plates of the ferroelectric capacitors. The second transistor and the first transistor have no difference from each other and have the same effect. Details are not described herein. In some embodiments, a first ferroelectric capacitor pair 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053.

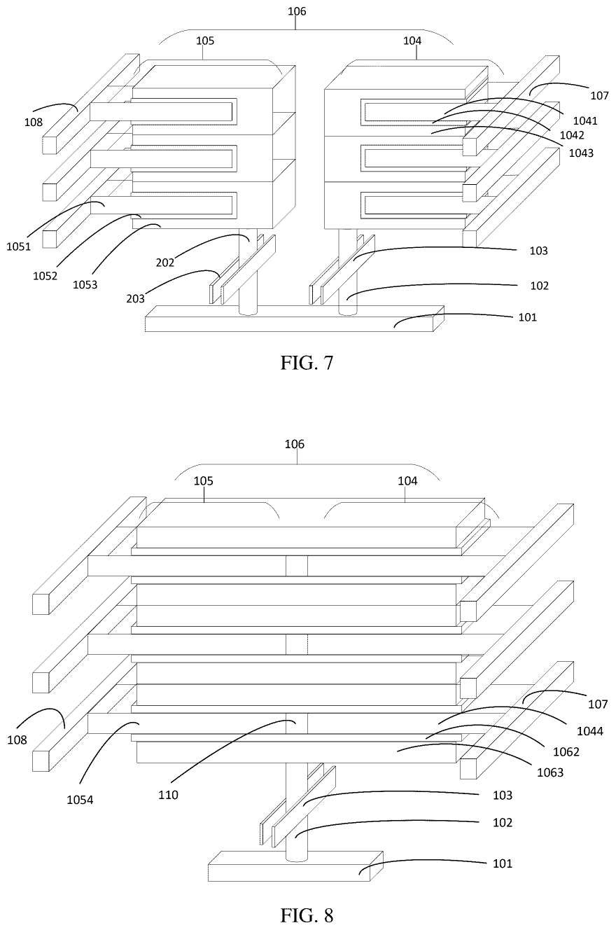

Still referring to FIG. 3, in some embodiments, the first upper electrode plate 1043 is not in contact with the second upper electrode plate 1053. The first upper electrode plate 1043 is connected to the first terminal of the first transistor 102, and the second upper electrode plate 1053 is connected to the second terminal of the second transistor 202. The first bit line 101, the first transistor 102, the first word line 103, and the first ferroelectric capacitor 104 constitute a basic ferroelectric memory cell structure, and the second bit line 101, the second transistor 202, the second word line 203, and the second ferroelectric capacitor 105 constitute a basic ferroelectric memory cell structure. Each of the basic ferroelectric memory cell structures can be controlled independently, which can reduce mutual crosstalk. Similarly, referring to FIG. 7, there may be multiple first ferroelectric capacitor pairs 106. Each of the first ferroelectric capacitor pairs 106 is stacked in a third direction, and the first upper electrode plate 1043 and the second upper electrode plate 1053 of each of the first ferroelectric capacitor pairs 106 are not in contact. However, multiple first upper electrode plates 1043 are stacked and connected together to be connected to the first terminal of the first transistor 102, and multiple second upper electrode plates 1053 are stacked and connected together to be connected to the first terminal of the second transistor 202. The multiple first ferroelectric capacitor pairs 106 are stacked in a compact manner in the third direction. This can reduce a quantity of transistors and increase a storage density. In addition, the first ferroelectric capacitor 104 and the second ferroelectric capacitor 105 of each of the multiple first ferroelectric capacitor pairs 106 are respectively and separately connected to the first transistor 102 and the second transistor 202, to constitute separate basic memory cell structures. This can reduce mutual crosstalk, implement precise control, and reduce energy consumption.

FIG. 4 is a schematic structural diagram of a ferroelectric memory according to an embodiment of this application. In some embodiments, a first ferroelectric capacitor pair 106 includes a first ferroelectric capacitor 104 and a second ferroelectric capacitor 105. A third lower electrode 1044 of the first ferroelectric capacitor 104 extends in a first direction, and a fourth lower electrode 1054 of the second ferroelectric capacitor extends in the first direction. The third lower electrode 1044 and the fourth lower electrode 1054 are not in contact with each other, but are connected through an insulating part 110. The third lower electrode 1044, the fourth lower electrode 1054, and the insulating part 110 are collinear in the first direction. The other terminal of the third lower electrode 1044 is connected to a first conducting wire 107, and the other terminal of the fourth lower electrode 1054 is connected to a second conducting wire 108. The third lower electrode 1044 and the fourth lower electrode 1054 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The third lower electrode 1044 and the fourth lower electrode 1054 may be made of the same material or different materials. The insulating part 110 is made of a material having an insulating property, which may be, e.g., at least one of the following materials: silicon nitride, silicon oxide, silicon oxynitride, and the like. In some other embodiments, the insulating part 110 may alternatively be made of some materials with a low dielectric constant or air. This can reduce a parasitic effect between the third lower electrode 1044 and the fourth lower electrode 1054. A third ferroelectric dielectric layer 1062 is arranged on surfaces of the third lower electrode 1044, the insulating part 110, and the fourth lower electrode 1054, and a third upper electrode plate 1063 is arranged on a surface of the third ferroelectric dielectric layer 1062. The third ferroelectric dielectric layer 1062 is located among the third lower electrode 1044, the fourth lower electrode 1054, and the third upper electrode plate 1063, so that the third lower electrode 1044, the fourth lower electrode 1054, and the third upper electrode plate 1063 are insulated from each other. The third ferroelectric dielectric layer 1062 is made of a material that may include a perovskite structure material, e.g., barium titanate (BaTiO₃) and a mixture Pb (Zr,Ti)O₃ of lead zirconate (PbZrO₃) and lead titanate (PbTiO₃), and may further include an HfO₂-based ferroelectric material implemented by doping at least one of zirconium (Zr), silicon (Si), lanthanum (La), yttrium (Y), strontium (Sr), gadolinium (Gd), and aluminum (Al) in an

HfO₂ material. The third ferroelectric dielectric layer may be made of the same material as or a material different from those of the first ferroelectric dielectric layer 1042 and the second ferroelectric dielectric layer 1052. This is not limited herein. The third upper electrode plate 1063 is made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The third lower electrode 1044 and the fourth lower electrode 1054 may be manufactured simultaneously, and the third ferroelectric dielectric layer 1062 and the third upper electrode plate 1063 each are a whole. This can simplify the manufacturing process and reduce production costs.

FIG. 8 is a schematic structural diagram of another ferroelectric memory according to an embodiment of this application. In some embodiments, multiple first ferroelectric capacitor pairs 106 are stacked in a third direction, and third upper electrode plates 1063 are connected to each other. In addition, the thickness of each of the third upper electrode plates 1063 can be adjusted to implement compact stacking in the third direction and increase a storage density. The third upper electrode plates 1063 are connected to each other in the third direction, so that the multiple first ferroelectric capacitor pairs can be integrally formed, thereby reducing process steps and production costs and improving production efficiency.

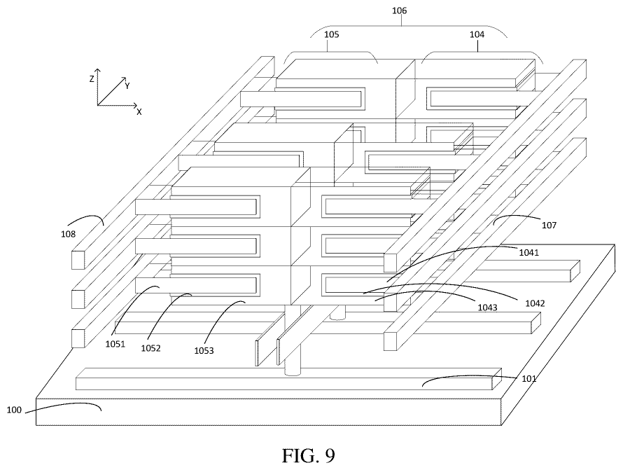

FIG. 9 is a schematic structural diagram of a three-dimensional ferroelectric memory according to an embodiment of this application. The schematic structural diagram of FIG. 9 may be obtained by arranging the ferroelectric memories of FIG. 1 and FIG. 5 in an array, with the ferroelectric memories being the same. A three-dimensional ferroelectric memory structure with an arrangement in three rows in a second direction and with three layers of first ferroelectric capacitor pairs stacked in a third direction is included in FIG. 9. In another embodiment, the array may include more ferroelectric memory structures arranged in the first direction and the second direction, and each of the ferroelectric memory structures may include more first ferroelectric capacitor pairs stacked in the third direction, with the first direction (e.g., X direction), the second direction (e.g., Y direction), and the third direction (Z direction) being perpendicular to each other, to form a three-dimensional memory array, thereby increasing the storage density.

Still referring to FIG. 9, in some embodiments, the three-dimensional ferroelectric memory includes a substrate 100, and first bit lines 101, first transistors 102 and first word lines 103, which are located on the substrate. The first bit lines 101 extend in the first direction (e.g., the X direction) and are arranged in the second direction (e.g., the Y direction). The first word lines extend in the second direction (e.g., the Y direction) and are arranged in the first direction (e.g., the X direction). The first transistors extend in the third direction (the Z direction) and are arranged in an array in the first direction (e.g., the X direction) and the second direction (e.g., the Y direction). Multiple first ferroelectric capacitor pairs 106 are stacked in the third direction (e.g., the Z direction) and are arranged in the second direction (e.g., the Y direction). Each of the first ferroelectric capacitor pairs 106 includes a first ferroelectric capacitor 104 and a second ferroelectric capacitor 105. The first ferroelectric capacitor 104 and the second ferroelectric capacitor 105 extend in the first direction (e.g., the X direction). Control terminals of the first transistors 102 are connected to the first word lines 103. Second terminals of the first transistors are connected to the first bit lines 101, and first terminals of the first transistors are connected to upper electrode plates of the first ferroelectric capacitor pairs. The multiple first ferroelectric capacitor pairs 106 are stacked in the third direction (e.g., the Z direction), which can reduce an occupied area and increase the storage density. The first ferroelectric capacitor 104 and the second ferroelectric capacitor 105 extend in the first direction (e.g., the X direction), so that a storage capacity of the ferroelectric capacitors can be adjusted by adjusting the length in the first direction (e.g., the X direction). This solves a sensing margin problem, and provides a sufficient floor area for the first transistor 102, which helps optimize a driving capability of the first transistor 102.

Still referring to FIG. 9, in some embodiments, the substrate 100 may be a monocrystalline silicon substrate, a polycrystalline silicon substrate, a germanium silicon substrate, a silicon carbide substrate, a silicon-on-insulator substrate, a germanium-on-insulator substrate, a glass substrate, a III-V compound substrate (e.g., silicon nitride or gallium arsenide), an oxide semiconductor substrate, or a substrate formed with a semiconductor device. In some embodiments, an NMOS (N-channel metal-oxide-semiconductor, N-channel metal-oxide-semiconductor) transistor, or a PMOS (P-channel metal-oxide-semiconductor, P-channel metal-oxide-semiconductor) transistor may be selected as the first transistor in the ferroelectric memory. For example, in a memory cell shown in FIG. 9, an NMOS transistor is selected as the first transistor. In this case, when a high voltage is applied to the first word line, the first transistor is turned on, or when a low voltage is applied to the first word line, the first transistor is turned off. In another embodiment, the first transistor may be a gate all around (gate all around), a triple gate, a double gate or a vertical single gate, or may be a planar transistor, a recessed transistor, or a buried transistor. A channel material of each of the first transistors 102 may be one or more of silicon (Si), polysilicon (poly-Si, p-Si), amorphous silicon (amorphous-Si, a-Si), an indium gallium zinc oxide (In—Ga—Zn—O, IGZO) multicomponent compound, zinc oxide (ZnO), ITO, titanium dioxide (TiO₂), molybdenum disulfide (MoS₂), and other semiconductor materials. This is not specifically limited in the embodiment of this application. In the embodiment of this application, only an example in which the first transistor 102 is a vertical double-gate transistor is taken for description.

Still referring to FIG. 9, in some embodiments, the control terminal of the first transistor 102 is referred to as a gate, and one of a drain (drain) or a source (source) of a MOS transistor is referred to as a first terminal, while the corresponding other terminal is referred to as a second terminal. For example, the first terminal of the first transistor may be the source while the second terminal may be the drain, or the first terminal is the drain while the second terminal is the source. The control terminals of the first transistors 102 arranged in the second direction (e.g., the Y direction) are connected to the first word lines 103, and the second terminals of the first transistors 102 arranged in the first direction (e.g., the X direction) are connected to the first bit lines 101. The first bit lines 101 and the first word lines 103 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first word line 103 and the first bit line 101 may be made of the same material or different materials.

Still referring to FIG. 9, in some embodiments, each of the first ferroelectric capacitor pairs 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053. The first ferroelectric dielectric layer 1042 and the second ferroelectric dielectric layer 1052 each are made of a material that may include a perovskite structure material, e.g., barium titanate (BaTiO₃) and a mixture Pb (Zr, Ti)O₃ of lead zirconate (PbZrO₃) and lead titanate (PbTiO₃), and may further include an HfO₂-based ferroelectric material implemented by doping at least one of zirconium (Zr), silicon (Si), lanthanum (La), yttrium (Y), strontium (Sr), gadolinium (Gd), and aluminum (Al) in an HfO₂ material. A material and a manufacturing process of a ferroelectric film layer are not limited in this application.

Still referring to FIG. 9, in some embodiments, the first lower electrode 1041, the second lower electrode 1051, the first upper electrode plate 1043, and the second upper electrode plate 1053 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first lower electrode 1041, the second lower electrode 1051, the first upper electrode plate 1043, and the second upper electrode plate 1053 may be made of the same material or different materials. The first upper electrode plate 1043 is in contact with the second upper electrode plate 1053, and the first terminal of the first transistor 102 is connected to the first upper electrode plate 1043 and the second upper electrode plate 1053. The multiple first ferroelectric capacitor pairs 106 are stacked in the third direction and are jointly connected to the first transistor 102. This can reduce a quantity of transistors and increase a storage density. In addition, the first upper electrode plate 1043 and the second upper electrode plate 1053 of each of the first ferroelectric capacitor pairs 106 are in contact, so that the upper electrode plates can be integrally formed. This reduces the difficulty of a manufacturing process, shortens a manufacturing time of the process, improves production efficiency, and reduces production costs.

Still referring to FIG. 9, in some embodiments, the three-dimensional ferroelectric memory further includes first conducting wires 107 and second conducting wires 108. The first conducting wires 107 and the second conducting wires 108 separately extend in the second direction (e.g., the Y direction) and are arranged in the third direction (e.g., the Z direction). The first conducting wires 107 are connected to first lower electrodes 1041 positioned on the same horizontal plane in the third direction (e.g., the Z direction) and arranged in the second direction (e.g., the Y direction). The second conducting wires 108 are connected to second lower electrodes 1051 positioned on the same horizontal plane in the third direction (e.g., the Z direction) and arranged in the second direction (e.g., the Y direction). This can reduce quantities of the first conducting wires 107 and the second conducting wires 108, reduce an occupied area, and increase the storage density. The first conducting wires 107 and the second conducting wires 108 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first conducting wire 107 and the second conducting wire 108 may be made of the same material or different materials.

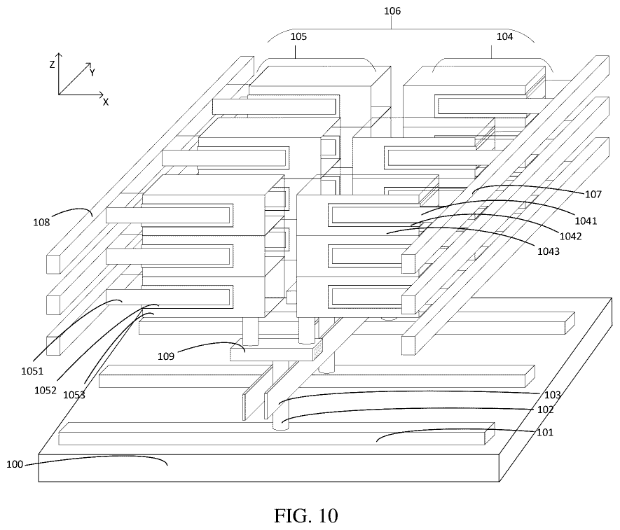

FIG. 10 is a schematic structural diagram of a three-dimensional ferroelectric memory according to an embodiment of this application. In some embodiments, a first ferroelectric capacitor pair 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053. The first upper electrode plate 1043 is not in direct contact with the second upper electrode plate 1053. A connecting part 109 is arranged at a first terminal of a first transistor. The connecting part 109 is separately connected to the first upper electrode plate 1043 and the second electrode plate 1053. A cross-section of the connecting part may be elliptical, rectangular, bench-shaped, or in another shape that enables the first upper electrode plate 1043 and the second upper electrode plate 1053 that are not connected to each other to be connected to the first transistor 102. The connecting part 109 is made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The first upper electrode plate 1043 and the second upper electrode plate 1053 are not in contact with each other, but are separately connected to the first transistor 102 through the connecting part 109. This can reduce crosstalk between the first ferroelectric capacitor 104 and the second ferroelectric capacitor 105 and improve performance of the ferroelectric memory. In addition, the first upper electrode plate 1043 and the second upper electrode plate 1053 of each of the first ferroelectric capacitor pairs 106 are not in contact with each other, and can be manufactured separately, thereby increasing a manufacturing window of the process, reducing the difficulty of a manufacturing process, and improving production efficiency.

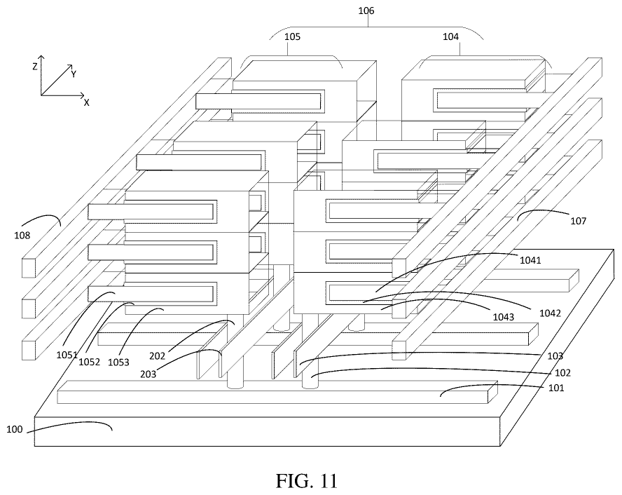

FIG. 11 is a schematic structural diagram of a three-dimensional ferroelectric memory according to an embodiment of this application. In some embodiments, the ferroelectric memory further includes a second transistor 202, a second word line 203, and a second bit line 101 (the second bit line and the first bit line may be shared or separated). A control terminal of the second transistor 202 is connected to the second word line 203.

A second terminal of the second transistor 202 is connected to the second bit line 101. A first terminal of the second transistor 202 and the first terminal of the first transistor 102 are respectively connected to upper electrode plates of the ferroelectric capacitors. The second transistor and the first transistor have no difference from each other and have the same effect. Details are not described herein. In some embodiments, a first ferroelectric capacitor pair 106 includes a first ferroelectric capacitor 104 and a second ferroelectric capacitor 105. The first ferroelectric capacitor 104 and the second ferroelectric capacitor 105 each include a lower electrode, a ferroelectric dielectric layer, and an upper electrode plate. A first lower electrode 1041 of the first ferroelectric capacitor extends in the first direction. A first ferroelectric dielectric layer 1042 is arranged on a surface of the first lower electrode 1041, and a first upper electrode plate 1043 is arranged on a surface of the first ferroelectric dielectric layer 1042. The first ferroelectric dielectric layer 1042 is located between the first lower electrode 1041 and the first upper electrode plate 1043 to insulate the first lower electrode 1041 from the first upper electrode plate 1043. A second lower electrode 1051 of the second ferroelectric capacitor 105 extends in the first direction, and a second ferroelectric dielectric layer 1052 is arranged on a surface of the second lower electrode 1051. A second upper electrode plate 1053 is arranged on a surface of the second ferroelectric dielectric layer 1052. The second ferroelectric dielectric layer 1052 is located between the second lower electrode 1051 and the second upper electrode plate 1053 to insulate the second lower electrode 1051 from the second upper electrode plate 1053.

Still referring to FIG. 11, in some embodiments, the first upper electrode plate 1043 is not in contact with the second upper electrode plate 1053. The first upper electrode plate 1043 is connected to the first terminal of the first transistor 102, and the second upper electrode plate 1053 is connected to the second terminal of the second transistor 202. The first bit line 101, the first transistor 102, the first word line 103, and the first ferroelectric capacitor 104 constitute a basic ferroelectric memory cell structure, and the second bit line 101, the second transistor 202, the second word line 203, and the second ferroelectric capacitor 105 constitute a basic ferroelectric memory cell structure. Each of the basic ferroelectric memory cell structures can be controlled independently, which can reduce 1mutual crosstalk, implement precise control, and reduce energy consumption.

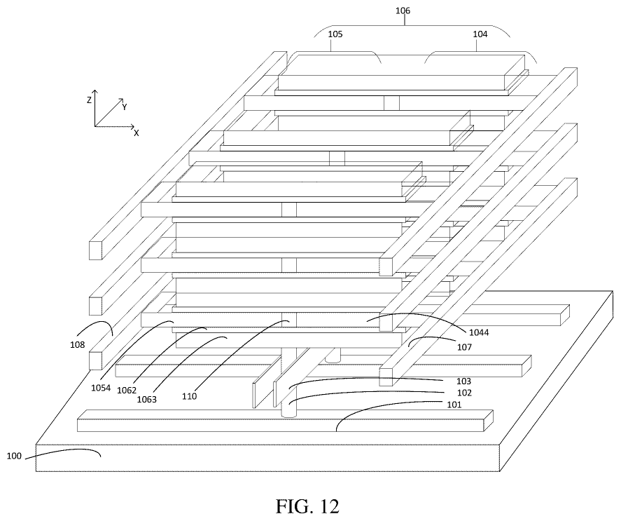

FIG. 12 is a schematic structural diagram of a three-dimensional ferroelectric memory according to an embodiment of this application. In some embodiments, a first ferroelectric capacitor pair 106 includes a first ferroelectric capacitor 104 and a second ferroelectric capacitor 105. A third lower electrode 1044 of the first ferroelectric capacitor 104 extends in a first direction, and a fourth lower electrode 1054 of the second ferroelectric capacitor extends in the first direction. The third lower electrode 1044 and the fourth lower electrode 1054 are not in contact with each other, but are connected through an insulating part 110. The third lower electrode 1044, the fourth lower electrode 1054, and the insulating part 110 are collinear in the first direction. The other terminal of the third lower electrode 1044 is connected to a first conducting wire 107, and the other terminal of the fourth lower electrode 1054 is connected to a second conducting wire 108. The third lower electrode 1044 and the fourth lower electrode 1054 each are made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The third lower electrode 1044 and the fourth lower electrode 1054 may be made of the same material or different materials. The insulating part 110 is made of a material having an insulating property, which may be, e.g., at least one of the following materials: silicon nitride, silicon oxide, silicon oxynitride, and the like. In some other embodiments, the insulating part 110 may alternatively be made of some materials with a low dielectric constant or air. This can reduce a parasitic effect between the third lower electrode 1044 and the fourth lower electrode 1054. A third ferroelectric dielectric layer 1062 is arranged on surfaces of the third lower electrode 1044, the insulating part 110, and the fourth lower electrode 1054, and a third upper electrode plate 1063 is arranged on a surface of the third ferroelectric dielectric layer 1062. The third ferroelectric dielectric layer 1062 is located among the third lower electrode 1044, the fourth lower electrode 1054, and the third upper electrode plate 1063, so that the third lower electrode 1044, the fourth lower electrode 1054, and the third upper electrode plate 1063 are insulated from each other. The third ferroelectric dielectric layer 1062 is made of a material that may include a perovskite structure material, e.g., barium titanate (BaTiO₃) and a mixture Pb (Zr, Ti)O₃ of lead zirconate (PbZrO₃) and lead titanate (PbTiO₃), and may further include an HfO₂-based ferroelectric material implemented by doping at least one of zirconium (Zr), silicon (Si), lanthanum (La), yttrium (Y), strontium (Sr), gadolinium (Gd), and aluminum (Al) in an HfO₂ material. The third ferroelectric dielectric layer may be made of the same material as or a material different from those of the first ferroelectric dielectric layer 1042 and the second ferroelectric dielectric layer 1052. This is not limited herein. The third upper electrode plate 1063 is made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The third lower electrode 1044 and the fourth lower electrode 1054 may be manufactured simultaneously, and the third ferroelectric dielectric layer 1062 and the third upper electrode plate 1063 each are a whole. This can simplify the manufacturing process and reduce production costs.

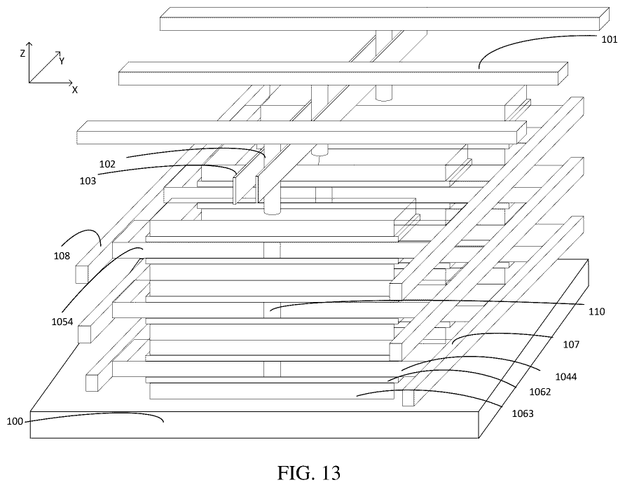

FIG. 13 is a schematic structural diagram of another three-dimensional ferroelectric memory according to an embodiment of this application. In some embodiments, the three-dimensional ferroelectric memory includes a substrate 100. First ferroelectric capacitor pairs 106 are located on the substrate. First word lines 103, first transistors 102, and first bit lines 101 are located on the first ferroelectric capacitor pairs 106. Multiple first ferroelectric capacitor pairs 106 are stacked in a third direction (e.g., Z direction) and are arranged in a second direction (e.g., Y direction). Each of the first ferroelectric capacitor pairs 106 includes a first ferroelectric capacitor 104 and a second ferroelectric capacitor 105. The first ferroelectric capacitor 104 and the second ferroelectric capacitor 105 extend in a first direction (e.g., X direction). The first bit lines 101 extend in the first direction (e.g., the X direction) and are arranged in the second direction (e.g., the Y direction). The first word lines extend in the second direction (e.g., the Y direction) and are arranged in the first direction (e.g., the X direction). The first transistors extend in the third direction (the Z direction) and are arranged in an array in the first direction (e.g., the X direction) and the second direction (e.g., the Y direction). Control terminals of the first transistors 102 are connected to the first word lines 103. Second terminals of the first transistors are connected to the first bit lines 101, and first terminals of the first transistors are connected to upper electrode plates of the first ferroelectric capacitor pairs. The first ferroelectric capacitor pairs 106, the first word lines 103, the first transistors 102, and the first bit lines 101 are not different from those in the previous embodiment, and have the same effect. Details are not described herein.

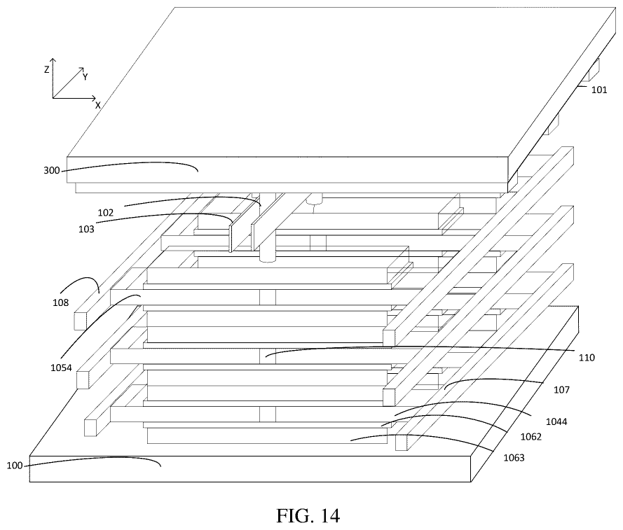

FIG. 14 is a schematic structural diagram of a three-dimensional ferroelectric memory device according to an embodiment of this application. The present disclosure further provides the three-dimensional ferroelectric memory device. As shown in FIG. 14, a back-end connecting wire (not shown) is arranged on a memory cell. The back-end connecting wire is located above a three-dimensional memory and is separately connected to a first word line 103 and a first bit line 101. The back-end connecting wire is made of a material having a conductive property, which may be, e.g., at least one of the following materials: titanium nitride (TiN), tungsten (W), nickel (Ni), platinum (Pt), titanium (Ti), tungsten nitride (WN), ruthenium (Ru), ruthenium oxide (RuOₓ), iridium (Ir), iridium oxide (IrOₓ), tantalum nitride (TaN), cobalt (Co), aluminum (Al), copper (Cu), polysilicon (p-Si), a metal silicide, and the like. The back-end connecting wire may be made of the same material as or a material different from those of the first word line 103 and the second bit line 101. In some embodiments, the three-dimensional ferroelectric memory device further includes a peripheral device wafer 300. Multiple peripheral circuit devices, e.g., a driving device, a decoding device, an error correction device, and other devices, are provided in the peripheral device wafer 300. The peripheral device wafer 300 is connected to the back-end connecting wire and is bonded to a wafer at which a ferroelectric memory is located.

The technical features in the foregoing embodiments may be combined arbitrarily. For brevity of description, not all possible combinations of these technical features in the foregoing embodiments are described. However, as long as these combinations of technical features are not contradictory, they should all be considered within the scope described in this specification.

The foregoing embodiments represent only several implementations of this application, and are described in a relatively specific and detailed way, but should not be construed as limitations on the patent scope of this application. It should be noted that a person of ordinary skill in the art can further make several variations and improvements without departing from the concept of this application, and these variations and improvements shall fall within the protection scope of this application. Therefore, the patent protection scope of this application shall be subject to the appended claims.

What is claimed is:

1. A ferroelectric memory, comprising:
a first word line, a first bit line, a first transistor, and a first ferroelectric capacitor pair,
the first ferroelectric capacitor pair comprising a first ferroelectric capacitor and a second ferroelectric capacitor, and the first ferroelectric capacitor and the second ferroelectric capacitor extending in a first direction; and
a control terminal of the first transistor being connected to the first word line, a second terminal of the first transistor being connected to the first bit line, and a first terminal of the first transistor being connected to upper electrode plates of the first ferroelectric capacitor pair.

2. The ferroelectric memory according to claim 1, wherein
the upper electrode plates comprise a first upper electrode plate and a second upper electrode plate;
a first lower electrode of the first ferroelectric capacitor extends in the first direction, a first ferroelectric dielectric layer is arranged on a surface of the first lower electrode, and the first upper electrode plate is arranged on a surface of the first ferroelectric dielectric layer; and
a second lower electrode of the second ferroelectric capacitor extends in the first direction, a second ferroelectric dielectric layer is arranged on a surface of the second lower electrode, and the second upper electrode plate is arranged on a surface of the second ferroelectric dielectric layer.

3. The ferroelectric memory according to claim 2, wherein
the first upper electrode plate is in contact with the second upper electrode plate, and the first terminal of the first transistor is in contact and connection with the first upper electrode plate and the second upper electrode plate.

4. The ferroelectric memory according to claim 2, wherein
the first upper electrode plate is not in contact with the second upper electrode plate, and the first terminal of the first transistor is in contact with the first upper electrode plate and the second upper electrode plate through a connecting part.

5. The ferroelectric memory according to claim 2, further comprising:
a second word line, a second bit line, and a second transistor,
a control terminal of the second transistor being connected to the second word line, and a second terminal of the second transistor being connected to the second bit line; and
the first upper electrode plate being not in contact with the second upper electrode plate, and the first terminal of the first transistor being in contact and connection with the first upper electrode plate; and a first terminal of the second transistor being in contact and connection with the second upper electrode plate.

6. The ferroelectric memory according to claim 1, wherein
the upper electrode plates further comprise a third upper electrode plate;
a third lower electrode of the first ferroelectric capacitor extends in the first direction, a fourth lower electrode of the second ferroelectric capacitor extends in the first direction, and the third lower electrode is connected to the fourth lower electrode through an insulating part; and
a third ferroelectric dielectric layer is arranged on surfaces of the third lower electrode and the fourth lower electrode, and the third upper electrode plate is arranged on a surface of the third ferroelectric dielectric layer.

7. The ferroelectric memory according to claim 1, further comprising:
a first conducting wire, the first conducting wire being connected to a lower electrode of the first ferroelectric capacitor; and
a second conducting wire, the second conducting wire being connected to a lower electrode of the second ferroelectric capacitor.

8. A three-dimensional ferroelectric memory, comprising:
a substrate;
a plurality of first bit lines, a plurality of first word lines, and a plurality of first transistors, the plurality of first word lines, the plurality of first bit lines, and the plurality of first transistors being located on the substrate;
the plurality of first bit lines extending in a first direction and being arranged in a second direction, the plurality of first word lines extending in the second direction and being arranged in the first direction, the plurality of transistors being arranged in the first direction and the second direction, and the first direction and the second direction intersecting; and
a plurality of first ferroelectric capacitor pairs, each of the first ferroelectric capacitor pairs comprising a first ferroelectric capacitor and a second ferroelectric capacitor, the first ferroelectric capacitor and the second ferroelectric capacitor extending in the first direction and being arranged in a third direction, and the first direction, the second direction, and the third direction intersecting with each other; and
the first word lines extending in the first direction being connected to control terminals of the first transistors arranged in the first direction, the first bit lines extending in the second direction being connected to second terminals of the first transistors arranged in the second direction, and first terminals of the first transistors being connected to upper electrode plates of the first ferroelectric capacitor pairs.

9. The three-dimensional ferroelectric memory according to claim 8, wherein
the upper electrode plates comprise a first upper electrode plate and a second upper electrode plate;
a first lower electrode of the first ferroelectric capacitor extends in the first direction, a first ferroelectric dielectric layer is arranged on a surface of the first lower electrode, and the first upper electrode plate is arranged on a surface of the first ferroelectric dielectric layer; and
a second lower electrode of the second ferroelectric capacitor extends in the first direction, a second ferroelectric dielectric layer is arranged on a surface of the second lower electrode, and the second upper electrode plate is arranged on a surface of the second ferroelectric dielectric layer.

10. The three-dimensional ferroelectric memory according to claim 9, wherein
the first upper electrode plate is in contact with the second upper electrode plate, and the first terminal of each of the first transistors is in contact and connection with the first upper electrode plate and the second upper electrode plate.

11. The three-dimensional ferroelectric memory according to claim 9, wherein
the first upper electrode plate is not in contact with the second upper electrode plate, and the first terminal of the first transistor is in contact with the first upper electrode plate and the second upper electrode plate through a connecting part.

12. The three-dimensional ferroelectric memory according to claim 9, further comprising:
a second word line, a second bit line, and a second transistor,
a control terminal of the second transistor being connected to the second word line, and a second terminal of the second transistor being connected to the second bit line; and
the first upper electrode plate being not in contact with the second upper electrode plate, and the first terminal of the first transistor being in contact and connection with the first upper electrode plate; and a first terminal of the second transistor being in contact and connection with the second upper electrode plate.

13. The three-dimensional ferroelectric memory according to claim 8, wherein
the upper electrode plates comprise a first upper electrode plate and a second upper electrode plate;
a third lower electrode of the first ferroelectric capacitor extends in the first direction, a fourth lower electrode of the second ferroelectric capacitor extends in the first direction, and the third lower electrode is connected to the fourth lower electrode through an insulating part; and
a third ferroelectric dielectric layer is arranged on surfaces of the third lower electrode and the fourth lower electrode, and the third upper electrode plate is arranged on a surface of the third ferroelectric dielectric layer.

14. The three-dimensional ferroelectric memory according to claim 8, further comprising:
a plurality of first conducting wires, the plurality of first conducting wires being respectively and correspondingly connected to lower electrodes of the first ferroelectric capacitor; and
a plurality of second conducting wires, the plurality of second conducting wires being respectively and correspondingly connected to lower electrodes of the second ferroelectric capacitor.

15. A three-dimensional ferroelectric memory device, comprising:
a three-dimensional ferroelectric memory, the three-dimensional ferroelectric memory being the three-dimensional ferroelectric memory according to claim 8; and
a peripheral device wafer, the peripheral device wafer being coupled to the three-dimensional ferroelectric memory.
